(19) United States
(12) Patent Application Publication
(10) Pub. No.: US 2006/0198175 A1
(43) Pub. Date: Sep. 7, 2006

(54) Method, system, and apparatus high speed interconnect to improve data rates of memory subsystems

(76) Inventors: Ashraf H. Badawi, Elk Grove, CA (US); Hany M. Fahmy, Sacramento, CA (US); Adam J. Norman, Forest Grove, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/072,953

(22) Filed: Mar. 3, 2005

(51) Int. Cl. G11C 5/02

(52) U.S. Cl. 365/51

(57) ABSTRACT

A technique is discussed for a different memory sub system topology to allow for separating impedance discontinuity The trace lengths from the MCH and the trace lengths to each memory device is calculated based at least in part on a frequency domain and time domain analysis. The new topology improves the impedance discontinuity that was evident in the P22P topology.

### BACKGROUND OF THE INVENTION

1. Field of the Invention

The present invention relates to interconnects for improving data rates of memory subsystems.

2. Description of the Related Art

For routing data (DQ) and strobe (DQS) signals, a typical arrangement for a double rank dual inline memory module (DIMM) is depicted in FIG. 1. A signal from a memory controller hub (MCH) arrives at both synchronous dynamic random access memories (SDRAM), depicted as U1 and U2, simultaneously. However, the parallel combination results in an impedance discontinuity that is twice the value of a single rank DIMM and results in limiting the performance of a memory sub-system at higher frequencies.

The main limiting factor for the maximum data transfer rate on a typical DDR type data channel is identified as the impedance discontinuity at the SDRAM receiver. The reason is that this impedance discontinuity resembles a low pass filter at the end of the transmission line connecting from the memory controller to the SDRAM receiver. This cutoff frequency of the low pass filter response corrupts the phase and attenuates the amplitudes of the relevant spectral components of the transmitted data signals. The resulting waveforms at the receiver will be distorted due to the presence of the low pass filter characteristic behavior. The simplest remedy is to restrict the data transfer rate to such that the majority power spectral frequency content of the transmitted signal is lower in frequency than the low pass cutoff frequency. This however limits the performance of the channel. Other remedies involve the re-design of the receiver such that it has better frequency response, a costly and time consuming solution.

### BRIEF DESCRIPTION OF THE SEVERAL VIEWS OF THE DRAWINGS

Subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 is a prior art figure

FIG. 2 is a schematic diagram in accordance with one embodiment.

FIG. 3 is a system in accordance with one embodiment.

FIG. 4 is a system in accordance with one embodiment.

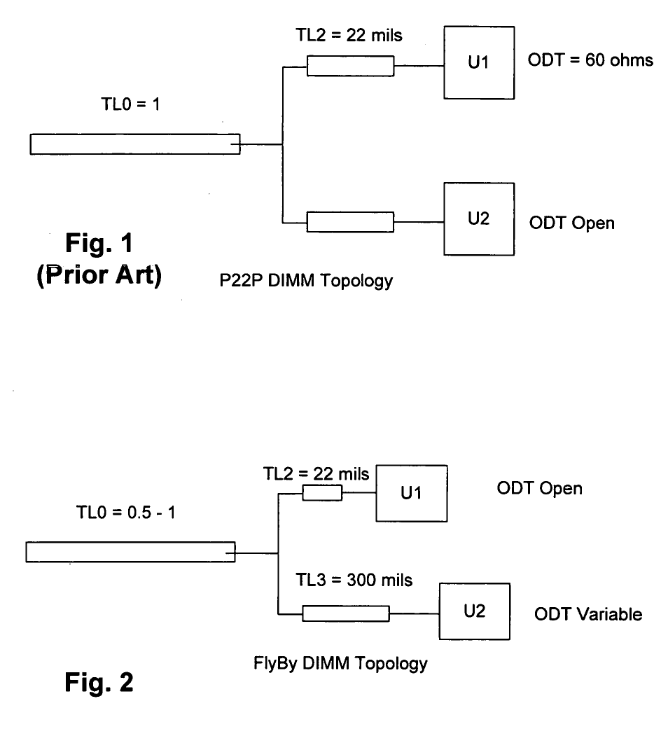

### DETAILED DESCRIPTION OF THE INVENTION

In the following description, for purposes of explanation, numerous details are set forth in order to provide a thorough understanding of the present invention. However, it will be apparent to one skilled in the art that these specific details are not required in order to practice the present invention.

An area of current technological development relates to improving transfer rates for memory subsystems. As previously described, the typical topology results in an impedance discontinuity that is twice the value of a single rank DIMM. Consequently, this results in limiting performance of a memory sub-system at higher frequencies. Other solutions require reducing device parasitics, however, this requires a complete redesign of the devices.

In contrast, a method, apparatus, and system that incorporates a different topology that does not require a total redesign of the devices is proposed that achieves a separation of the impedance discontinuity.

FIG. 2 is a schematic diagram in accordance with one embodiment. This figure depicts three trace lengths, TL0, TL2 and TL3. TLO is a trace length from a MCH, TL2 is a trace length to one DIMM (depicted as U1), and TL3 is another trace length to the other DIMM (depicted as U2). In one embodiment, the TL0 may range between 0.5 to 1 inches. In the same embodiment, TL2 is 22 millimeters and TL3's length is determined by the following:

Frequency and time domain based optimization algorithms were used to select TL3's trace length. Likewise, an analysis between the effect of separating the two impedance discontinuities versus the effect of the added routing length. One final consideration is the effect of the increased stub length as seen by device U1.

In one aspect, the technique splits the two memory loads as suggested here the doubling of the impedance discontinuity is removed. For writing to the first device (closer to the memory controller) the second device will terminate the transmission line, and the length between the two devices is selected such that this length is transparent at frequency components of interest. Thus creating effectively an impedance transformer for the transmission line. For writing to the second device the transmission line will already be terminated at its end and the added length between the first and the second device constitutes a small amount of added parasitics to the channel such that the performance is not affected. Frequency domain and time domain analysis is done on the channel to carefully select the length between the first and the second device to achieve the required impedance transformation effect. Therefore, the result is trying to match the impedance when moving from the second device to the first one to get channel with matched impedance and minimum insertion loss.

To summarize, the two memory devices on the DIMM are on the receiving end for data during alternate times in different write cycles. When writing to each device from the memory controller, the termination presented by the other device is shaped by the transmission line length between these two devices. So the optimization algorithm minimizes the reflection and impedance discontinuity presented by this stub, by varying the required length while monitoring all the relevant channel parameters. The resulting length optimally matches the impedance at the respective receiver device for the specific data transfer rate targeted by the system designer.

Also, in one embodiment, the trace length analysis may be implemented in software. For example, the software may be stored in an electronically-accessible medium that includes any mechanism that provides (i.e., stores and/or transmits) content (e.g., computer executable instructions) in a form readable by an electronic device (e.g., a computer, a personal digital assistant, a cellular telephone).For example, a machine-accessible medium includes read only memory (ROM); random access memory (RAM); magnetic disk storage media; optical storage media; flash memory devices; electrical, optical, acoustical or other form of propagated signals (e.g., carrier waves, infrared signals, digital signals).

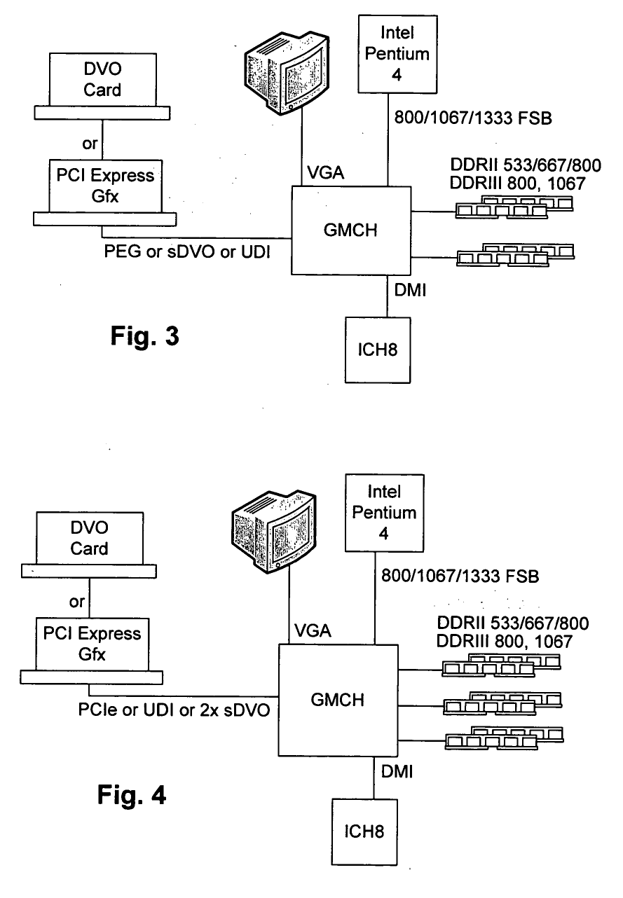

FIG. 3 is a system as utilized by one embodiment. The MCH receives inputs from either a DVO card or PCI Express interface. In one embodiment, the MCH receives inputs from an UDI (Unified Display Interface) muxed over PEG. In one embodiment, the system incorporates the techniques described for trace length calculation described earlier for choosing the trace length from the MCH to the DDR Dram devices (DDRII and DDRIII generation).

FIG. 4 is a system as utilized by another embodiment. The MCH receives inputs from either a PCIe or UDI or 2x sDVO. In one embodiment, the system incorporates the techniques described for trace length calculation described earlier for choosing the trace length from the MCH to the DDR Dram devices (DDRII and DDRIII generation).

Although the claimed subject matter has been described with reference to specific embodiments, this description is not meant to be construed in a limiting sense. Various modifications of the disclosed embodiment, as well as alternative embodiments of the claimed subject matter, will become apparent to persons skilled in the art upon reference to the description of the claimed subject matter. It is contemplated, therefore, that such modifications can be made without departing from the spirit or scope of the claimed subject matter as defined in the appended claims.

Basically the two devices on the DIMM are on the receiving end for data during alternate times in different write cycles. When writing to each device from the controller the stub length between the two devices become very critical, as the termination presented by the other device is shaped by the transmission line length between these two devices. So the optimization algorithm minimizes the reflection and impedance discontinuity presented by this stub, by varying the required length while monitoring all the relevant channel parameters. The resulting length optimally matches the impedance at the respective receiver device for the specific data transfer rate targeted by the system designer.

1. A method for selecting a topology comprising:
splitting a first and a second memory load such that a first load is closer to a source than a second load;
writing to the first load, a first memory device, while the second load, a second memory device, terminates a transmission line; and
selecting a different trace length for the first and second load such that the based at least in part on a frequency component.

2. The method of claim 1 wherein the first and second memory device are a DDRII or DDRIII DRAM generation.

3. The method of claim 1 wherein the source is a MCH.

4. The method of claim 1 wherein the source is a GMCH.

5. The method of claim 1 further comprising:
writing to the second load, a second memory device, since the transmission line is already terminated at its end such that the added length between the first and the second memory device constitutes a small amount of added parasitics; and
performing a frequency domain and time domain analysis on a memory channel to select a trace length between the first and the second memory device to achieve the required impedance transformation effect.

6. A method for selecting a topology comprising:
splitting a first and a second memory load such that a first load is closer to a source than a second load;
writing to the first load, a first memory device, while the second load, a second memory device, terminates a transmission line;
selecting a different trace length for the first and second load such that the based at least in part on a frequency component;
writing to the second load, a second memory device, since the transmission line is already terminated at its end such that the added length between the first and the second memory device constitutes a small amount of added parasitics; and
performing a frequency domain and time domain analysis on a memory channel to select a trace length between the first and the second memory device to achieve the required impedance transformation effect.

7. The method of claim 6 wherein the first and second memory device are a DDRII or DDRIII DRAM generation.

8. The method of claim 6 wherein the source is a MCH.

9. The method of claim 6 wherein the source is a GMCH.

10. A method for selecting a trace length from a MCH to a first and a second memory device comprising:
splitting a first and a second memory load such that a first load is closer to a source than a second load;
writing to the first load, the first memory device, while the second load, the second memory device, terminates a transmission line;
selecting a different trace length for the first and second load such that the based at least in part on a frequency component;
writing to the second load, a second memory device, since the transmission line is already terminated at its end such that the added length between the first and the second memory device constitutes a small amount of added parasitics; and
performing a frequency domain and time domain analysis on a memory channel to select a trace length between the first and the second memory device to achieve the required impedance transformation effect.

11. The method of claim 10 wherein the first and second memory device are a DDRII or DDRIII DRAM generation.

12. The method of claim 10 wherein the source is a MCH.

13. The method of claim 10 wherein the source is a GMCH.

14. An article of manufacture comprising:
a machine-readable medium having a plurality of machine readable instructions, wherein when the instructions are executed by a system, the instructions provides to selecting a trace length from a MCH to a first and a second memory device comprising:
splitting a first and a second memory load such that a first load is closer to a source than a second load;
writing to the first load, the first memory device, while the second load, the second memory device, terminates a transmission line;
selecting a different trace length for the first and second load such that the based at least in part on a frequency component;
writing to the second load, a second memory device, since the transmission line is already terminated at its end such that the added length between the first and the second memory device constitutes a small amount of added parasitics; and
performing a frequency domain and time domain analysis on a memory channel to select a trace length between the first and the second memory device to achieve the required impedance transformation effect.

15. The article of manufacture of claim 14 wherein the first and second memory device are a DDRII or DDRIII DRAM generation.

16. The article of manufacture of claim 14 wherein the source is a MCH.

17. The article of manufacture of claim 14 wherein the source is a GMCH.

18. A system comprising:
a processor, coupled to a MCH, to send memory requests to the MCH;
a first and a second memory device, to be connected to the MCH such that
a trace length is chosen by splitting a first and a second memory load such that a first load is closer to the MCH than a second load;
the second load, the second memory device, terminates a transmission line when writing to the first load, the first memory device;
selecting a different trace length for the first and second load such that the based at least in part on a frequency component.

19. The system of claim 18 further comprising:
that when MCH writes to the second load, the second memory device, the transmission line is already terminated at its end such that the added length between the first and the second memory device constitutes a small amount of added parasitics.

20. The system of claim 18 wherein the first and second memory device are a DDRII or DDRIII DRAM generation.

21. A method for impedance matching for a first and a second memory device comprising:
receiving data at the first and a second memory device data during alternate times in different write cycles;
shaping the termination presented by the second memory device when writing data to the first memory, based at least in part on a transmission line length; and
varying a trace length while monitoring parameters of a memory channel.

22. The method of claim 21 wherein writing data to the first memory device is from a memory controller.

23. A method for impedance matching for a first and a second memory device comprising:
receiving data at the first and a second memory device data during alternate times in different write cycles;
shaping the termination presented by the second memory device when writing data to the first memory, based at least in part on a transmission line length;
varying a trace length while monitoring parameters of a memory channel, wherein the trace length; and
optimally matches the impedance at the first memory device for a predetermined data transfer rate.

24. The method of claim 21 wherein writing data to the first memory device is from a memory controller.

25. A system comprising:
a processor, coupled to a MCH, to send memory requests to the MCH;
a first and a second memory device, to be connected to the MCH such that the first and the second memory device receive data during alternate times in different write cycles;
the termination presented by the second memory device when writing data to the first memory, is altered based at least in part on a transmission line length;
a trace length is varied while monitoring parameters of a memory channel, wherein the trace length; and
optimally matches the impedance at the first memory device for a predetermined data transfer rate.

26. The system of claim 25 wherein the first and second memory device are a DDRII or DDRIII DRAM generation.
